(19) United States
(12) Patent Application Publication
(10) Pub. No.: US 2011/0262767 A1
(43) Pub. Date: Oct. 27, 2011

(54) SURFACE HARDENED SUBSTRATE AND METHOD MAKING SAME

(75) Inventors: HSIN-PEI CHANG, Tu-Cheng (TW); WEN-RONG CHEN, Tu-Cheng (TW); CHENG-SHI CHEN, Tu-Cheng (TW); HUAN-WU CHIANG, Tu-Cheng (TW); YI-CHI CHAN, Tu-Cheng (TW); HUA-YANG XU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/884,674

(22) Filed: Sep. 17, 2010

(30) Foreign Application Priority Data
Apr. 23, 2010 (CN) 201010153748.7

(51) Int. Cl. B32B 15/04; C23C 14/14; B32B 15/00

(52) U.S. Cl. 428/621; 428/656; 428/680; 428/615; 204/192.1

(57) ABSTRACT

A surface hardened substrate includes a base, a transition layer disposed on a surface of the base, and a hard layer disposed on the transition layer. The transition layer includes at least two kinds of transition metals. The hard layer includes an alloy and a nonmetal. The alloy includes the at least two kinds of transition metals.

### CROSS-REFERENCE TO RELATED APPLICATION

This application claims all benefits accruing under 35 U.S.C. §119 from China Patent Application No. 201010153748.7, filed on Apr. 23, 2010, in the China

Intellectual Property Office, disclosure of which is incorporated herein by reference. This application is related to an application entitled, “SURFACE HARDENED SUBSTRATE AND METHOD MAKING SAME,” filed **** (Atty. Docket No. US30314).

### BACKGROUND

1. Technical Field

The present disclosure relates to a surface hardened substrate and a method for making the same.

2. Description of Related Art

An enhanced film generally is disposed on a surface of a substrate such as a watch shell, an eyeglass frame, a mobile telephone, or a computer, to protect the substrate from being scratched. The enhanced film can have a high wearing resistance, and a high mechanical hardness.

However, the enhanced film such as chromium carbide (CrC) film, or chromium nitride (CrN) film, is brittle. There is a low bonding tension between the enhanced film and the substrate such that the enhanced film is prone to get broken off from the substrate.

What is needed, therefore, is to provide a surface hardened substrate with an enhanced film disposed thereon and a method making the surface hardened substrate, in which the enhanced film is difficult to break off from the substrate.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic structural view of an embodiment of a surface hardened substrate.

FIG. 2 shows a glow discharge optical emission spectrometry (GD-OES) image of the surface hardened substrate of the embodiment shown in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

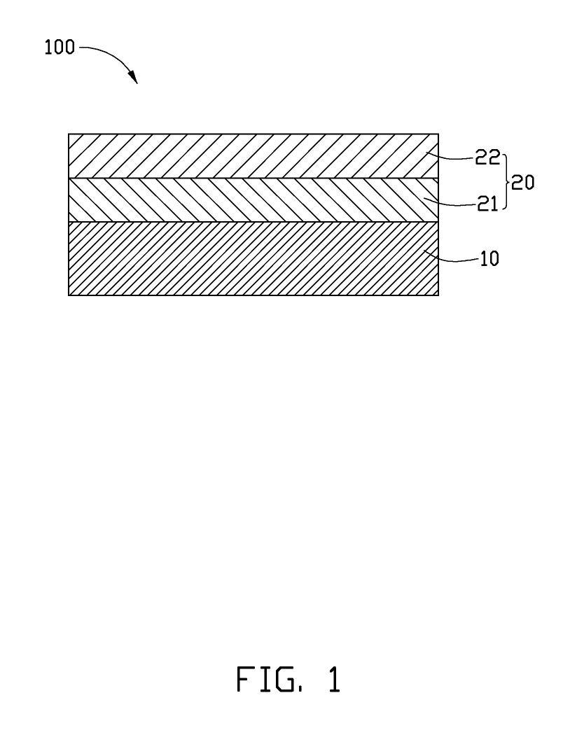

Referring to FIG. 1, one embodiment of a surface hardened substrate 100 is shown. The surface hardened substrate 100 includes a base 10 and an enhanced film 20 disposed on a surface of the base 10.

The base 10 can be a watch shell, an eyeglass frame, a mobile telephone, or a computer. The base 10 can be a metal-based base such as a magnesium-based base, an aluminum-based base, or an iron-based base. The base 10 can be a composite-based base including a metal complex. In one embodiment, the base 10 is steel-based.

The enhanced film 20 can cover the surface of the base 10 and protect the base 10 from being eroded or scratched. The enhanced film 20 can have a thickness greater than about 200 nanometers. In one embodiment, the enhanced film 20 has a thickness from about 500 nanometers to about 5 micrometers. The enhanced film 20 can be a multilayer structure. The enhanced film 20 can include a transition layer 21 disposed on the surface of the base 10, and a hard layer 22 disposed on the transition layer 21.

The transition layer 21 is substantially sandwiched between the base 10 and the hard layer 22 to improve an adhesion between the base 10 and the hard layer 22. The transition layer 21 can include nickel (Ni) and chromium (Cr). The transition layer 21 can be an alloy based on the nickel and the chromium. The nickel can composite with the chromium to form a Ni—Cr alloy. The nickel has good tenacity, and stability in high temperature, and good adhesion with the base 10. The chromium can improve the mechanical hardness of the transition layer 21. The nickel in the transition layer 21 can have a weight percentage from about 20 percent to about 80 percent, and can have a thickness from about 100 nanometers to about 3 micrometers. In one embodiment, to improve an adhesion between the base 10 and the enhanced film 20 and save a cost of the transition layer 21, the weight percentage of the nickel is about 60 percent, and the thickness of the transition layer 21 is about 150 nanometers.

The hard layer 22 can be disposed on a surface of the transition layer 21 away from the base 10. The hard layer 22 can include a composite including an alloy and a chromium compound. The alloy can include nickel, chromium, nitrogen (N), and carbon (C). The nickel and the chromium can form a Ni—Cr—N alloy with the nitrogen, a Ni—Cr—C alloy with the carbon, or a Ni—Cr—N—C alloy with the nitrogen and the carbon. In one embodiment, the alloy is a Ni—Cr—C alloy. The chromium compound can be chromium carbide (CrC), chromium nitride (CrN), or combination thereof. A hard phase composite can be formed by combining nitrogen or carbon with chromium to improve mechanical hardness and wear resistance of the composite. The hard phase does not contain the nickel. The chromium compound can also have high mechanical hardness and high wear resistance to protect the composite from being scratched. Thus, the hard layer 22 consisting of the composite can have high mechanical hardness and high wear resistance. Both the transition layer 21 and the hard layer 22 can have nickel and chromium, thus, the transition layer 21 and the hard layer 22 can be tightly adhered together. A thickness of the hard layer 22 can be designed according to what is practical for intended application. In one embodiment, the thickness of the hard layer 22 is in a range from about 100 nanometers to about 3 micrometers. Weight percentages of nickel, chromium, and nitrogen or carbon can be designed according to what as is practical for intended application. The nitrogen in the hard layer 22 can have a weight percentage from about 1 percent to about 50 percent. The carbon in the hard layer 22 can have a weight percentage from about 1 percent to about 50 percent. The weight percentage of the nitrogen plus the weight percentage of the carbon can be about 1 percent to about 90 percent. In one embodiment, the hard layer 22 obtains excellent adhesion with the transition layer 21 and high mechanical hardness, if the weight percentage of nickel is about 50 percent, the weight percentage of chromium is about 30 percent, and the weight percentage of carbon is about 20 percent.

The transition metals in the transition layer 21 and the hard layer 22 cannot be limited. If only two kinds of the transition metals can be contained in the transition layer 21 and the hard layer 22. The transition metals in the transition layer 21 are substantially the same as the transition metals in the hard layer 22. The transition metals can also be rhodium, cobalt, manganese, titanium, tungsten, palladium, cadmium, zirconium, or combinations thereof. One of the at least two kinds of the transition metals, such as nickel, or titanium, can have an excellent adhesion with the base 10. The other one of the two kinds of the at least two kinds of transition metals, such as tungsten, or chromium, can form a hard phase with the nonmetal to improve the mechanic hardness and the wearing resistance of the enhanced film 20. The hard phase does not contain the nickel.

The enhanced film 20 can be firmly fixed on the base 10, due to the excellent adhesion of the transition layer 21. Thus, the enhanced film 20 can be tightly adhered to the base 10. The hard layer 22 having high mechanical hardness and high wearing resistance can protect the base 10 from being scratched. In addition, both the transition layer 21 and the hard layer 22 can have the at least two kinds of transition metals such as nickel and chromium therein, therefore, a thermal expansion coefficient of the transition layer 21 can be substantially equal to a thermal expansion coefficient of the hard layer 22.

A Young's modulus of the transition layer 21 can be similar to a Young's modulus of the hard layer 22. When a temperature of the surface hardened substrate 100 is changed, a volume of the enhanced film 20 will change with the temperature. A deformation of the transition layer 21 can be substantially equal to a deformation of the hard layer 22, thus, an intensity of internal stress formed in the enhanced film 20 can be decreased. Thus, the enhanced film 20 can be difficult to brake off from the base 10.

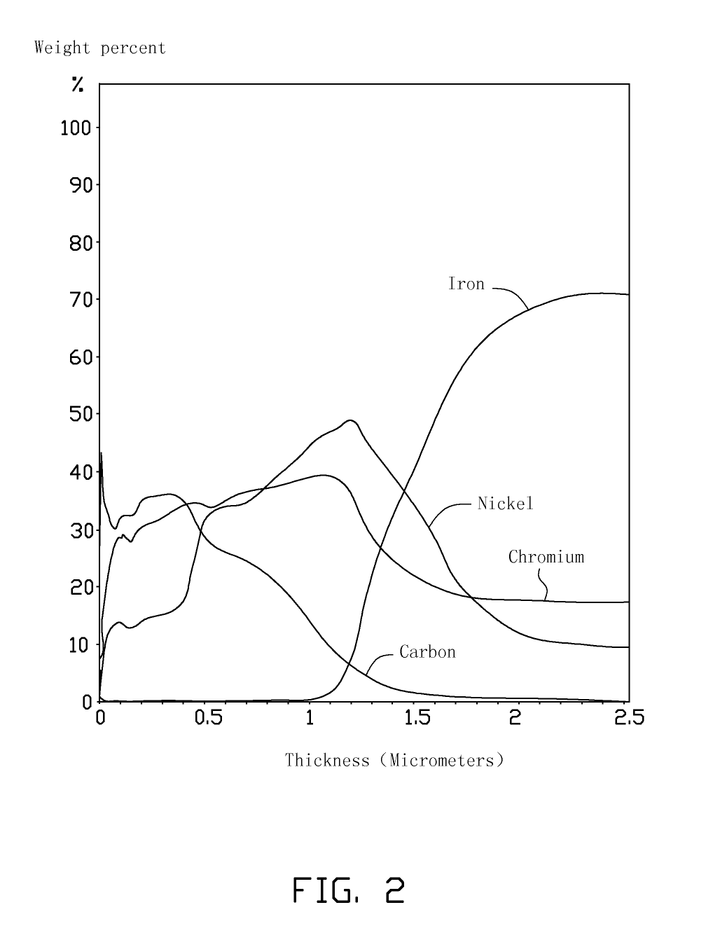

A depth profile analysis of an embodiment the surface hardened substrate 100 can be carried out by glow discharge optical emission spectrometry (GD-OES). Materials in the hardened substrate 100, such as, iron, nickel, chromium and carbon have smooth curves as shown in FIG. 2. The materials can be distributed at different depths.

The enhanced film 20 is a multilayer structure, however, the materials in the transition layer 21 or the base 10 can be distributed in the hard layer 22, and materials in the hard layer 22 can also be distributed in the transition layer 21. Therefore, the enhanced film 20 can be defined as a composite film. A first side of the composite film, adjacent to the base 10, can include more alloy. A second side of the alloy film opposite the base 10 can include more chromium compound, such as chromium carbide (CrC).

One embodiment of a method for making the surface hardened substrate 100 in FIG. 1 can include the following steps:
S10, providing a base 10;
S20, forming a transition layer 21 on a surface of the base 10, the transition layer 21 comprising at least two kinds of transition metals; and
S30, applying a hard layer 22 on the transition layer 21, wherein the hard layer 22 comprises an alloy and a chromium compound, and the alloy comprises the at least two kinds of transition metals.

Step S10, can comprise cleaning the base 10. The step of cleaning can be performed by the following steps: S11, cleaning a surface of the base 10 ultrasonically in a solvent; and S12, plasma cleaning the base 10 with an inert gas in a vacuum environment.

In step S11, the solvent can be an organic solvent such as an acetone or an ethanol. In steps S12, the vacuum environment can be provided in a chamber of a sputtering device. The inert gas can be argon or helium dispersed in the chamber. In one embodiment, a degree of vacuum can be about 3*10⁻⁵ Torre. The base 10 is bombarded with the pure argon in the sputtering device from about 3 minutes to about 10 minutes.

In step S20, the base 10 can have a temperature from about 100 degrees to about 200 degrees. The transition layer 21 can firmly secured to the base 10, if the temperature is between about 100 degrees to about 200 degrees. The transition layer 21 can be formed on the base 10 by means of sputtering and formed by the following step: S21, bombarding a sputtering alloy target including the at least two kinds of transition metals and forming the transition layer 21 on the surface of the substrate 100.

In step S21, the sputtering alloy target can be a Ni—Cr alloy target including nickel and chromium. The nickel in the Ni—Cr alloy target can have a weight percentage from about 20 percent to about 80 percent. When the Ni—Cr alloy target is turned on for about 20 minutes to about 60 minutes, a Ni—Cr alloy layer having a thickness from about 100 nanometers to about 3 micrometers can be formed on the surface of the base 10.

In step S30, the hard layer 22 can be formed by means of sputtering and disposed by the following steps: S31, introducing a gas to the transition layer 21, wherein the gas can be a carbonaceous gas, a nitrogenous gas, or combination thereof; and S32, alternately bombarding an alloy sputtering target, comprising the at least two kinds of transition metals, and a chromium sputtering target a plurality of times.

In step S31, the carbonaceous gas can be acetylene or methane. The nitrogenous gas can be nitrogen gas or ammonia gas. In one embodiment, the gas is acetylene.

In step S32, when the at least two kinds of transition metals are bombarded using the alloy sputtering target, the at least two kinds of transition metals can react with the gas to form an enhanced alloy deposited on the transition layer 21. When using the chromium sputtering target, the chromium can react with the gas to form chromium compound deposited on the transition layer 21. When the alloy sputtering target and the chromium sputtering target are alternately bombarded, the enhanced alloy and the chromium compound form a composite together. Thus, the composite including the enhanced alloy and the chromium compound can be obtained. For example, the chromium sputtering target can be bombarded for 5 minutes, and then the alloy sputtering target can be bombarded for 5 minutes, and repeated as needed.

In one embodiment, the alloy sputtering target is a Ni—Cr alloy target, and the gas is carbonaceous gas. The Ni—Cr can react with the carbonaceous gas to form a Ni—Cr—C enhanced alloy. The chromium can react with the carbonaceous gas to form chromium carbide. Thus, the hard layer 22 including the Ni—Cr—C enhanced alloy and the chromium carbide can be formed on the transition layer 21.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

It is to be understood that the above-described embodiments are intended to illustrate rather than limit the present disclosure. Any elements described in accordance with any embodiments is understood that they can be used in addition or substituted in other embodiments. Embodiments can also be used together. Variations may be made to the embodiments without departing from the spirit of the disclosure. The above-described embodiments illustrate the scope, but do not restrict the scope of the disclosure.

What is claimed is:

1. A surface hardened substrate comprising:
a base;
a transition layer located on a surface of the base, the transition layer comprising at least two kinds of transition metals; and
a hard layer located on the transition layer, the hard layer comprising an alloy and a chromium compound;
wherein the alloy comprises the at least two kinds of transition metals.

2. The surface hardened substrate of claim 1, wherein the base comprises a metal or a composite.

3. The surface hardened substrate of claim 1, wherein the at least two kinds of transition metals are selected from the group consisting of nickel, chromium, rhodium, cobalt, manganese, titanium, tungsten, palladium, cadmium, zirconium, and combinations thereof.

4. The surface hardened substrate of claim 1, wherein the transition layer is an alloy layer formed by nickel and chromium.

5. The surface hardened substrate of claim 4, wherein the nickel of the transition layer has a weight percentage of about 20 percent to about 80 percent.

6. The surface hardened substrate of claim 1, wherein the alloy in the hard layer further comprises a nonmetal, the nonmetal is selected from the group consisting of nitrogen, carbon, and combinations thereof.

7. The surface hardened substrate of claim 6, wherein the alloy comprises nickel, chromium, and nitrogen.

8. The surface hardened substrate of claim 7, wherein the alloy comprises a hard phase, the hard phase comprises the nitrogen and the chromium in the alloy, wherein the hard phase does not contain the nickel.

9. The surface hardened substrate of claim 6, wherein the alloy comprises nickel, chromium, and carbon.

10. The surface hardened substrate of claim 9, wherein the alloy comprises a hard phase, the hard phase comprises the carbon and the chromium in the alloy, the hard phase does not contain the nickel.

11. The surface hardened substrate of claim 6, wherein the hard layer comprises nickel, chromium, nitrogen, and carbon.

12. The surface hardened substrate of claim 11, wherein the nitrogen of the hard layer has a weight percentage from 0 percent to about 50 percent, the carbon of the hard layer has a weight percentage from 0 percent to about 50 percent, and the weight percentage of the nitrogen plus the weight percentage of carbon is in a range from about 1 percent to about 90 percent.

13. The surface hardened substrate of claim 1, wherein a thickness of the transition layer plus a thickness of the hard layer is in a range from about 500 nanometers to 5 micrometers.

14. The surface hardened substrate of claim 13, wherein the transition layer has a thickness from about 100 nanometers to about 3 micrometers.

15. The surface hardened substrate of claim 1, wherein the chromium compound is selected from the group consisting of chromium carbide, chromium nitride, and combinations thereof.

16. A method for making a surface hardened substrate, comprising:
providing a base;
applying a transition layer on a surface of the base, wherein the transition layer comprises at least two kinds of transition metals; and
forming a hard layer on the transition layer, the hard layer comprising an alloy and a chromium compound, and the alloy comprising the at least two kinds of transition metals.

17. The method of claim 16, wherein the transition layer and the hard layer are formed by means of sputtering.

18. The method of claim 16, wherein the step of forming the transition layer comprising:
bombarding an alloy sputtering target comprising the at least two kinds of transition metals, and forming the transition layer on the surface of the base.

19. The method of claim 16, wherein the step of forming the hard layer comprising:
introducing a gas to the transition layer, the gas being selected from the group consisting of a carbonaceous gas, a nitrogenous gas, and combination thereof; and
alternately bombarding an alloy sputtering target, comprising the at least two kinds of transition metals, and a chromium sputtering target a plurality of times.

20. The method of claim 19, wherein the carbonaceous gas is selected from the group consisting of an acetylene, a methane, and combinations thereof; and the nitrogenous gas is selected from the group consisting of a nitrogen gas, an ammonia gas, and combinations thereof.
